(19) United States
(12) Patent Application Publication
(10) Pub. No.: US 2009/0027060 A1
(43) Pub. Date: Jan. 29, 2009

(54) ADAPTER AND INTERFACE AND ELECTRONIC DEVICE TEST APPARATUS PROVIDED WITH ADAPTER

(75) Inventors: Daisuke Takano, Tokyo (JP); Yoshiyuki Masuo, Tokyo (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 11/912,709

(22) PCT Filed: May 18, 2006
(86) PCT No.: PCT/JP2006/309950

§ 371 Date: Oct. 26, 2007

(30) Foreign Application Priority Data
Jun. 7, 2005 (JP) 2005-167151

(51) Int. Cl. G01R 1/02

(52) U.S. Cl. 324/537

(57) ABSTRACT

An adapter able to reduce the costs of an electronic device test apparatus, the adapter having a frame member interposed, between an opening formed at a handler and a HIFIX attached to a test head and inserted in the opening for adapting the shape of the HIFIX to the shape of the opening.

### BACKGROUND OF THE INVENTION

1. Field of the Invention

The present invention relates to an adapter for adapting the shape of an interface attached to a test head to an opening formed in a handler in an electronic device test apparatus for testing semiconductor integrated circuit chips or other electronic devices (hereinafter referred to as “ICs”) and an interface and electronic device test apparatus provided with the adapter.

2. Description of the Related Art

In an electronic device test apparatus, a large number of ICs held an a tray are conveyed into a handler, the ICs are brought into electrical contact with IC sockets provided at an interface at the test head, and the ICs are tested by a tester that is a main body of an electronic device test apparatus. Further, the ICs finished being tested are classified onto corresponding customer trays based on the categories of test results.

The test head is mechanically connected to an opening formed in the handler. Above the test head is attached a HIFIX (interface) for interconnecting electrical connection between the ICs under test at the handler side and the test head. HIFIXes are produced and used depending on differences in the type of the ICs to be tested and in the number of simultaneous measurements.

In recent electronic device test systems, the number of simultaneous measurements (number of ICs which can be simultaneously tested) has been increasing to 64, 128, and 256. For this reason, even if arranging the IC sockets at narrower pitches, the HIFIXes cannot be maintained constant in outer size like in the past, and the openings formed in the handlers have been becoming larger. For this reason, sometimes the openings differ in size depending on the type of the handlers.

A HIFIX has to be fabricated to handle the opening of the type of the handler and to handle the ICs under test or number of simultaneous measurements. Therefore, a HIFIX has to be produced, and prepared, in different external sizes for the different types of handlers. For this reason, there was the problem that the large number of HIFIXes used in conventional handlers could not be connected to new handlers. However, HIFIXes are expensive devices, so fabrication of new HIFIXes leads to an increase in capital costs and higher test costs.

### SUMMARY OF THE INVENTION

The present invention has as its object the provision of an adapter able to reduce the costs of electronic device test apparatus and an interface and electronic device test apparatus provided with the adapter.

(1) To achieve the above object, according to the present invention, there is provided an adapter interposed between an opening formed in a handler and an interface attached to a test head and inserted into the opening and adapting a shape of the interface to the shape of the opening (see claim 1).

In the present invention, an adapter is used to adapt the shape of an existing HIFIX to an opening of a handler, so even if the opening of the handler is made larger, the existing HIFIX can be used as it is.

While not particularly limited in the above invention, preferably the adapter has a frame member adapting a shape of an insertion part of the interface to be inserted into the opening to a shape of the opening (see claim 2).

While not particularly limited in the above invention, preferably the adapter has a frame member adapting a shape of the opening to a shape of an insertion part of the interface to be inserted into the opening (see claim 3).

While not particularly limited in the above invention, preferably the frame member has a recessed cross-sectional shape surrounding the outer circumference of the insertion part (see claim 4).

Due to this cross-sectional shape, the adapter can be pre-attached to the interface before connecting the interface to the handler.

While not particularly limited in the above invention, preferably the insertion part in the interface is a spacing frame of the interface (see claim 5).

While not particularly limited in the above invention, preferably the frame member has an upper layer part and a lower layer part joined below the upper layer part, the upper layer part is comprised of a material having a lower heat conductivity than the material forming the lower layer part, and the lower layer part is comprised of a material having a higher strength than the material forming the upper layer part (see claim 6).

In the present invention, the frame member is comprised of a multilayer structure having an upper layer part and a lower layer part. Further, the upper layer part may be made of a material with a low heat conductivity to secure a heat insulating property so as to maintain the temperature environment in a chamber of the handler. As opposed to this, the lower layer part may be made of a material with a high strength to secure a strength able to withstand a pressing force applied to an IC under test at the time of the test.

(2) To achieve the above object, according to the present invention, there is provided an interface attached to a test head for testing an electronic device under test and interconnecting an electrical connection between the electronic device under test and the test head, the interface provided with an adapter as set forth in any one of claims 1 to 6 (see claim 7).

In the present invention, the adapter is pre-set to an interface before inserting the interface into an opening of the handler. Due to this, the work of attaching the adapter becomes work from the top, so the work efficiency is superior.

(3) To achieve the above object, according to the present invention, there is provided with an electronic device test apparatus comprising a test head to which an electronic device under test is electrically connected, a tester for testing the electronic device under test through the test head, and a handler for feeding a pretest electronic device to the test head and discharging a tested electronic device from the test head, wherein the electronic device test apparatus comprises an adapter as set forth in any one of claims 1 to 6 (see claim 8).

While not particularly limited in the above invention, preferably the handler comprises a holding means for holding an interface, the adapter is interposed between the holding means and the interface, and the holding means holds the adapter so that the interface is held (claim 9).

While not particularly limited in the above invention, preferably a second holding member of substantially the same shape as a first holding member provided at the interface for abutting against the holding means is provided at the adapter, and the holding means abuts against the second holding member so that the holding means holds the adapter.

While not particularly limited in the above invention, the handler comprises positioning means for positioning the interface with respect to the handler, the adapter is interposed between the positioning means and the interface, and the positioning means positions the adapter so that the interface is positioned with respect to the handler (see claim 10).

While not particularly limited in the above invention, preferably the positioning means includes first positioning pins, second positioning holes of substantially the same shape as first positioning holes provided at the interface for insertion of the first positioning pins are provided at said adapter and second positioning pins of substantially the same shape as the first positioning pins are provided at the adapter, and the first positioning pins are inserted into the second positioning holes and the second positioning pins are inserted into the first positioning holes, whereby the interface is positioned with respect to the handler (see claim 11).

While not particularly limited in the above invention, preferably the handler comprises a sealing means for sealing the space between the opening and interface, the adapter is interposed between the sealing means and the interface, and the sealing means seals the space between the opening and the adapter (see claim 12).

(4) To achieve the above object, according to the present invention, there is provided an adapter interposed between an opening formed in a handler and an interface attached to a test head, and connecting the handler and the interface, the adapter engaging with the interface to connect the handler and the interface (see claim 13).

Further, to achieve the above object, according to the present invention, there is provided an adapter interposed between an opening formed in a handler and an interface attached to a test head and connecting the handler and the interface, the adapter interposed between an incompatible design interface not designed so as to match with the shape of the opening and the opening, and connecting the handler and the incompatible design interface (see claim 14).

While not particularly limited in the above invention, preferably the adapter is attached by being fixed to the opening formed in the handler or is attached by being fixed to the interface (see claim 15).

### BRIEF DESCRIPTION OF THE DRAWINGS

FIG. 1 is a perspective view showing an overview of an electronic device test apparatus according to an embodiment of the present invention;

FIG. 2 is a cross-sectional view along the line II-II of FIG. 1;

FIG. 3 is a back view of an electronic device test apparatus shown in FIG. 1;

FIG. 4 is a detailed cross-sectional view showing a HIFIX and test head according to an embodiment of the present invention;

FIG. 5 is a perspective view showing the overall configuration of an adapter according to an entailment of the present invention;

FIG. 6 is a perspective view shying the state of a HIFIX connected, to a handler using an adapter according to an embodiment of the present invention;

FIG. 7 is a cross-sectional view along the line VII-VII of FIG. 6; and

FIG. 8 is an enlarged cross-sectional view of the part VIII of FIG. 7.

### DESCRIPTION OF THE PREFERRED EMBODIMENTS

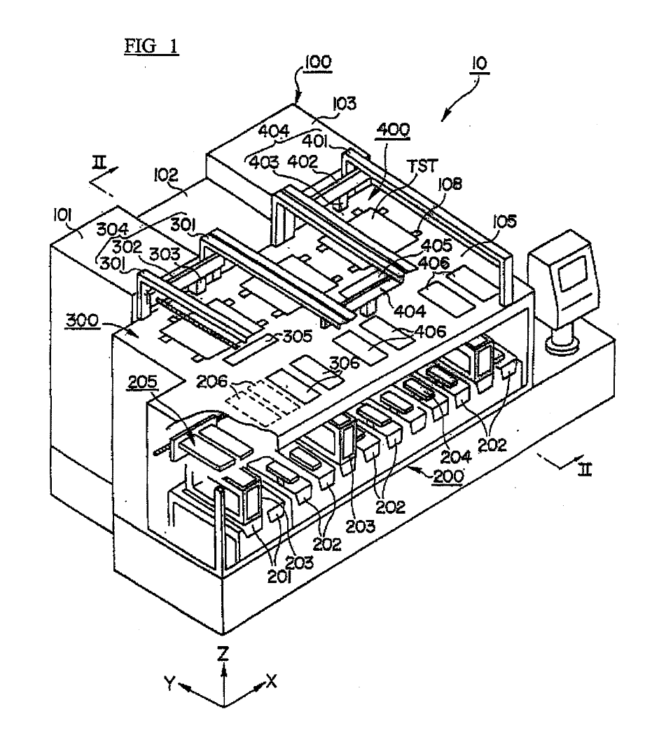

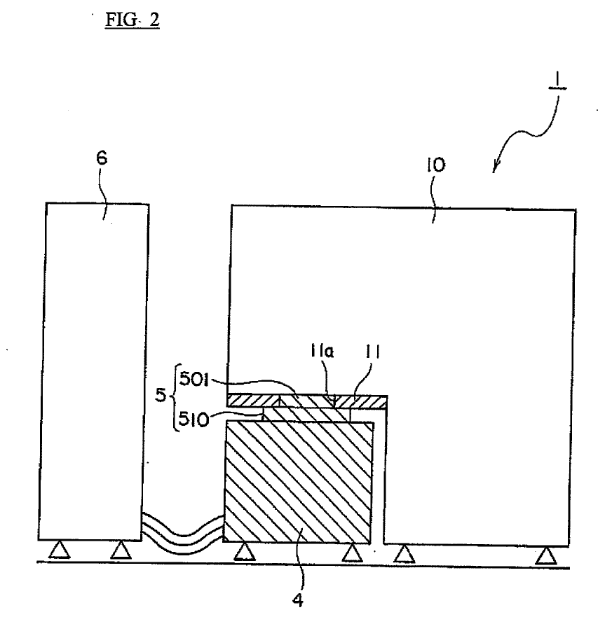

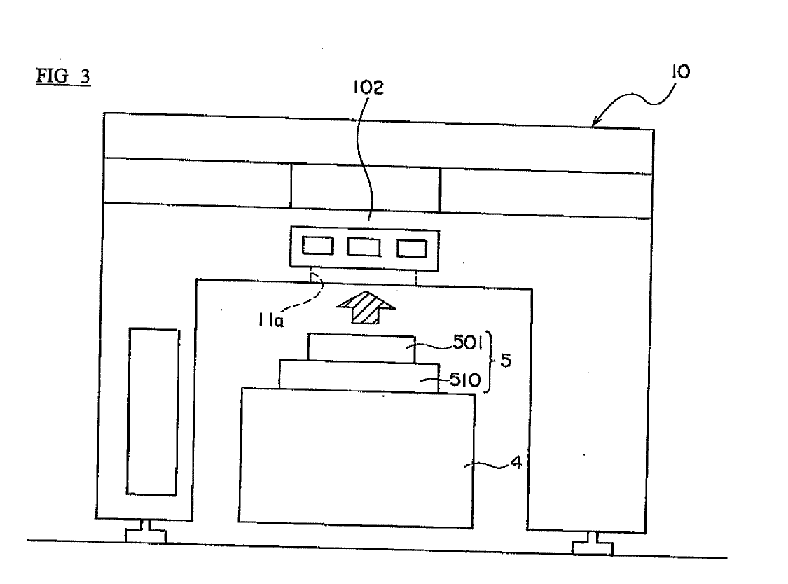

Below, an embodiment of the present invention will be explained based on the drawings. FIG. 1 is a perspective view showing an overview of an electronic device test apparatus according to an embodiment of the present invention, FIG. 2 is a schematic cross-sectional view along the line II-II of FIG. 1, and FIG. 3 is a back view of an electronic device test apparatus shown in FIG. 1. First, referring to FIG. 1 to FIG. 3, the overall configuration of an electronic device test apparatus according to the present embodiment will be briefly explained.

The electronic device test apparatus 1 according to the present embodiment, as shown in FIG. 1 and FIG. 2, comprises a handler 10 for handling the ICs under test, a test head 4 to which the ICs under test are electrically connected, and a tester 6 for sending test signals to this test head 4 and testing the ICs under test.

The handler 10 is a device which applies high temperature or low temperature thermal stress to the ICs, brings them into electrical contact with the IC sockets 506 at the HIFIX 5 side for testing by the tester 6, and classifies the ICs based on the information of the test results from the tester 6. Further, it reloads the ICs under test from a customer tray holding a large number of ICs under test (hereinafter referred to as a “customer tray”) to a test tray conveyed through the inside of the handler 10 for conveyance, heating/cooling, testing, and classification.

Each test tray is loaded with ICs under test at the loader 300, then is sent to a chamber 100. In the state loaded on the test tray, the ICs under test are brought into contact with the IC sockets 506 of the test head 4 and tested in a chamber 100. Further, the ICs finished being tested are unloaded to the unloader 400, then the ICs on the customer trays are reloaded in accordance with the test results in the unloader 400.

The chamber unit 100 comprises a thermostatic chamber 101 for applying a targeted high temperature or low temperature thermal stress to the ICs under test loaded on a test tray, a test chamber 102 bringing the ICs under test in the state given thermal stress by this thermostatic chamber 101 into contact with the test head, and a destress chamber 103 for removing the applied thermal stress from the ICs under test tested at the test chamber 102.

When applying a high temperature in the thermostatic chamber 101, the ICs under test are cooled by blowing air to return them to room temperature in the destress chamber 103. Further, when applying a low temperature of for example about −30° C. in the thermostatic chamber 101, the ICs under test are heated by warm air or a heater etc. in the destress chamber 103 to return them to a temperature of an extent where no condensation occurs. Further, the ICs under test from which the stress is removed are carried out to the unloader 400.

As shown in FIG. 2 and FIG. 3, a base 11 of the handler 10 forming the bottom of the test chamber 102 is formed at its approximate center with an opening 11a. Inside this opening 11a, a HIFIX 5 attached to the top of the test head 4 is connected. A test tray is carried to above the IC sockets 506 of this HIFIX 5, where the large number of ICs under test on the test tray are simultaneously brought into electrical contact with the HIFIX 5 (strictly speaking, the contact pins of the IC sockets 506) for testing. The test results are stored at addresses determined by for example the identification numbers assigned to the test trays and the serial numbers of the ICs under test assigned at the insides of the test trays. A test tray finished being tested is treated at the destress chamber 103 and is discharged to the unloader 400 after the ICs are returned to roan temperature. Note that the configurations of the HIFIX 5 and the area around the opening 11a of the handler 10 will be explained later.

The IC storage unit 200 is provided with pretest IC stackers 201 for storing ICs before a test and tested IC stockers 202 for storing ICs after a test classified in accordance with the test results.

The pretest IC stockers 201 and the tested IC stockers 202 have tray support frames 203 and elevators 204 able to enter from the bottom of the tray support frames 203 and rise upward. The tray support frames 203 support pluralities of not shown customer trays stacked up. These stacked up customer trays are moved up and down by the elevators 204.

Further, the pretest IC stockers 201 hold the customer trays storing the ICs before testing stacked up. The tested IC stockers 202 hold the customer trays based on the information of the test results stacked up.

Each customer tray is loaded into the loader 300. The ICs under test is reloaded to a test tray in the loader 300.

As the conveyance system for reloading ICs under test from a customer tray to a test tray, as shown in FIG. 1, an X-Y conveyance system 304 provided with two rails 301 laid an a board 105, a movable arm 302 able to move back and forth between a test tray and a customer tray by the two rails 301 (this direction being referred to as the “Y-direction”), and a movable head 303 supported by this movable arm 302 and able to move in the X-direction along the movable arm 302 is used.

The movable head 303 of this X-Y conveyance system 304 has suction heads attached to it. The suction heads pick up ICs under test by suction and reload them from a customer tray to a test tray. For example, about eight suction heads are attached the movable head 303 enabling eight ICs under test to be reloaded to the test tray at one time.

The board 105 of the loader 300 is formed with a pair of windows 306, 306 at which customer trays conveyed to the loader 300 are arranged so as to approach the top surface of the board 105. While not illustrated, the windows 306 are provided with holding hooks for holding customer trays conveyed to the windows 306. The customer trays are held at positions where the top surfaces of the customer trays approach the surface of the board 105 through the windows 306.

Further, the windows 306 are provided below them with elevator tables for raising and lowering the customer trays. Customer trays emptied after reloading of the pretest ICs there are lowered. The empty trays are transferred to the tray transport arm 205.

The unloader 400 is also provided with X-Y conveyance systems 404, 404 of the same structure as the X-Y conveyance system 304 provided at the loader 300. These X-Y conveyance systems 404 reload the tested ICs under test from a test tray carried to the unloader 400 to a customer tray.

The board 105 of the unloader 400 is formed with two pairs of windows 406, 406 arranged so that the customer trays carried to the unloader 400 approach the top surface of the board 105. While not illustrated, the windows 406 are provided with holding hooks for holding customer trays carried to the windows 406. The customer trays are held at positions where the top surfaces of the customer trays approach the surface of the board 105 through the windows 406.

Further, the windows 406 are provided below them with elevator tables for raising and lowering the customer trays. Customer trays filled after reloading of the tested ICs there are lowered. The full trays are transferred to the tray transport arm 205.

As shown in FIG. 1, above the pretest IC stockers 201 and tested IC stockers 202 is provided a tray transport arm 205 for moving across the entire range of the direction of arrangement of the pretest IC stockers 201 and tested IC stockers 202 in the space between the board 105.

This tray transport arm 205 is provided with a pair of tray holders for holding the customer trays arranged in the left-right direction. This transfers customer trays between the leader 300, the unloader 400, the pretest IC stockers 201 and the tested IC stockers 202.

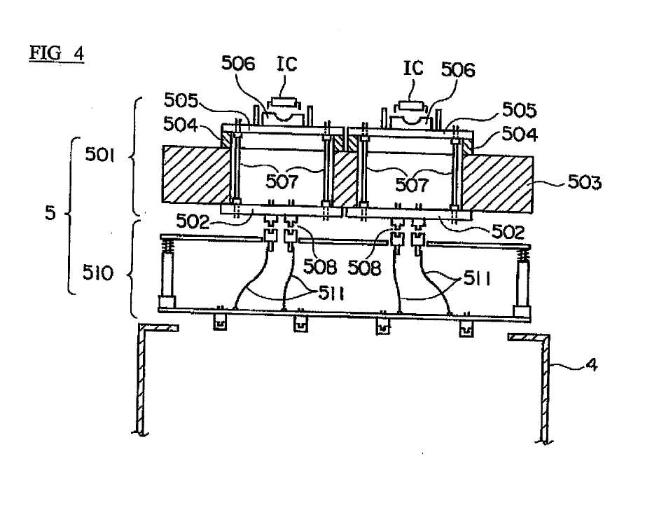

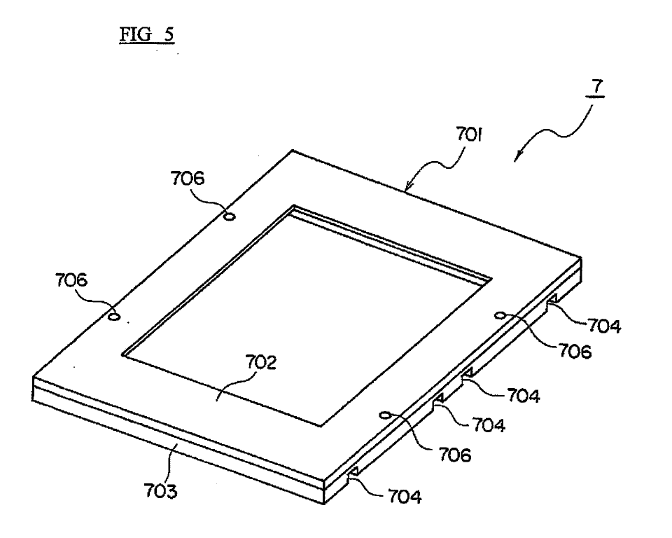

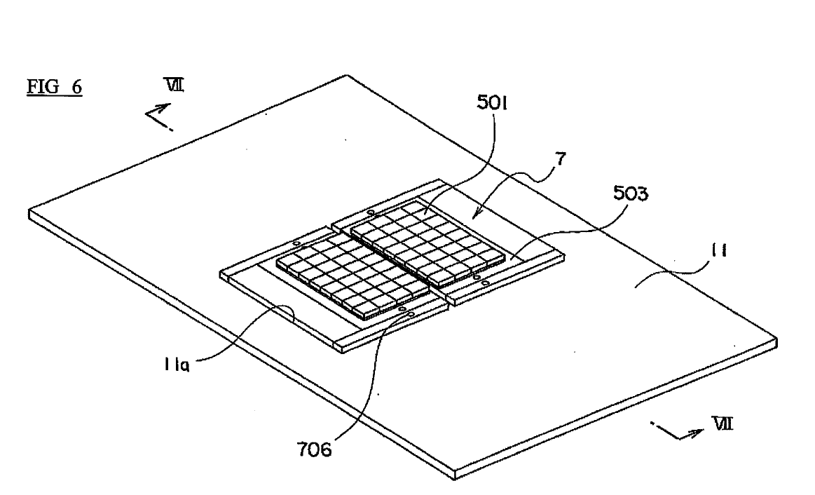

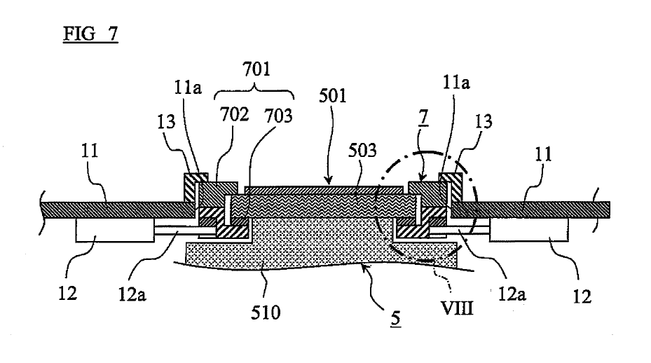

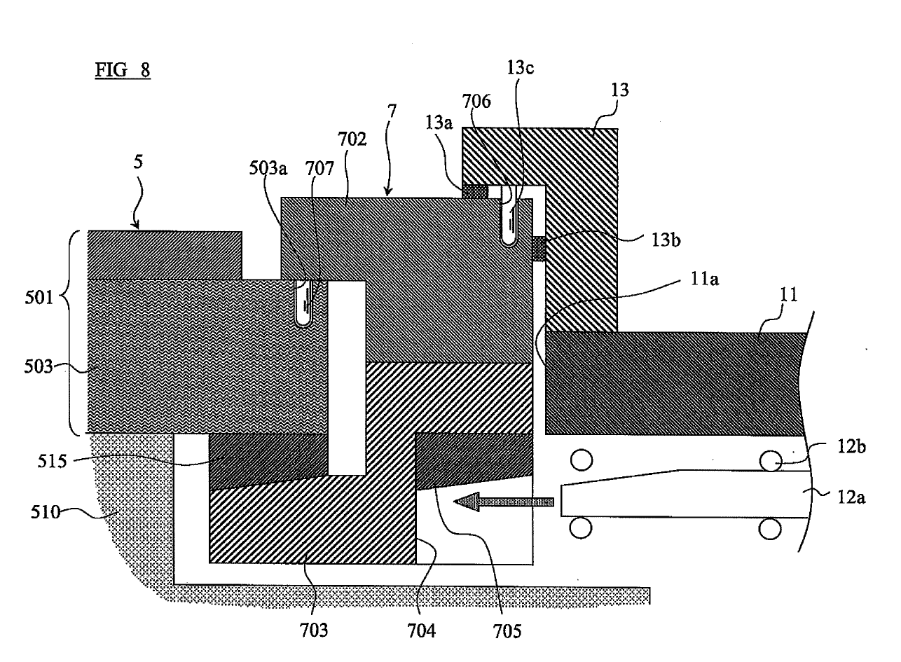

FIG. 4 is a detailed cross-sectional view showing a HIFIX and test head according to an embodiment of the present invention, FIG. 5 is a perspective view showing the overall configuration of an adapter according to an embodiment of the present invention, FIG. 6 is a perspective view showing the state of a HIFX connected to a handler using an adapter according to an embodiment of the present invention, FIG. 7 is a cross-sectional view along the line VII-VII of FIG. 6, and FIG. 8 is an enlarged cross-sectional view of the part VIII of FIG. 7.

Next, an HIFIX 5 in the present embodiment will be explained.

The HIFIX 5, as shown in the structural example of FIG. 4, is comprised of a mother board 510 attached to the top of the test head 4 and a device specific adapter (DSA) 501 attached to this mother board 510.

The DSA 501 is comprised of an interconnect board 502 above which a spacing frame 503 is provided and further, above top, a socket board spacer 504 through which a socket board 505 is provided. The socket board 505 has a large number of sockets 506 mounted on it to correspond to the array of ICs under test held an a test tray. Note that the internal structure of the DSA 501 shown in FIG. 4 is an example.

The interconnect board 502 and the socket board 505 are connected by connector boards 507. Further, the interconnect board 502 is provided with connectors 508 for attachment to and separation from the mother board 510. The connectors 508 are connected to coaxial connectors 511 through the corresponding connectors at the mother board 510 side. Due to this, the ICs under test and test head 4 are electrically connected.

The DSA 501 is a part designed and produced to correspond to the type of the ICs under test and the number of simultaneous measurements and to be adapted to the opening 11a of a specific handler. The mother board 510 is a part used in camion without regard as to the type of the ICs under test or the number of simultaneous measurements. Therefore, when changing the type of the ICs under test, it is possible to change only the DSA 501 to one corresponding to the type of the ICs under test so as to handle the type of the ICs under test or the number of simultaneous measurements.

The spacing frame 503 of the DSA 501 is provided at its bottom surface, as shown in FIG. 8, with a first clamp piece 515 made of for example stainless steel or another metal material. When connecting a HIFIX designed so as to be compatible with the size of the opening 11a (hereinafter referred to as simply a “compatible design HIFIX”) to the handler 10, a rod 12a of a cylinder 12 provided at the handler 10 (explained later) contacts and presses this first clamp piece 515.

Note that a compatible design HIFIX is newly designed to match with a handler having a large opening corresponding to the increase in the number of simultaneous measurements, while the HIFIX 5 in the present embodiment is an existing HIFIX (incompatible design HIFIX) which cannot be connected to a handler as it is. Further, usually, in the state where the later explained adapter 5 is not attached, the size becomes smaller than the size of the opening 11a of the handler 10.

The spacing frame 503 of the DSA 501 is, as shown in FIG. 8, formed at its top surface with first positioning holes 503a. When connecting a compatible design HIFIX to the handler 10, first positioning pins 13c of the sealing member 13 provided at the handler 10 (explained later) are inserted into this first positioning holes 503a.

Next, the configuration of the area around the opening 11a of the handler 10 will be explained while referring to FIG. 7 and FIG. 8.

As shown in the drawing, around the opening 11a of the handler 10, a cylinder 12 for holding the HIFIX 5 with respect to the handler 10 and a sealing member 13 for sealing the space between the opening 11a and the HIFIX 5 are provided. Note that FIG. 6 does not show the cylinder 12 and sealing member 13.

The cylinder 12 is an air type, hydraulic, or electric powered cylinder leaving an extendable rod 12a. This cylinder 12 is provided at the bottom surface of the base 11 of the handler 10 in a posture with direction of extension of the rod 12a facing the opening 11a side. The rod 12a is extendably supported by a plurality of shafts 12b provided at its circumference. When connecting the compatible design HIFIX to the handler 10, the HIFIX is held with respect to the handler 10 by the front end of the rod 12a of this cylinder 12 contacting and pressing against the first clamp piece 515 provided at the HIFIX.

As shown in FIG. 8, the front end of the rod 12a is tapered. Further, the bottom surface of the first clamp piece 515 provided at the HIFIX 5 is tapered. Therefore, when connecting a compatible design HIFIX with the handler 10, if the rod 12a contacts the first clamp piece 515, the wedge action causes the HIFIX to be pushed upward.

The sealing member 13 is a substantially L-shape member comprised of, for example, a glass epoxy resin etc. This sealing member 13 is provided at the top surface of the base 11 of the handler 10 so as to cover the peripheral edge of the opening 13a. The wall surface of the inside of this sealing member 13 has, as shown in FIG. 8, packings 13a, 13b made of for example silicone rubber attached to it. When connecting a compatible design HIFIX to the handler 10, if the cylinder 12 pushes the first clamp piece 515, the packings 13a, 13b of the sealing member 13 seal the space between the HIFIX 5 and the opening 11a of the handler 10 to seal the high temperature/low temperature state atmosphere inside the handler from the outside air. However, in the case of a handler used only at ordinary temperature, the packings 13a, 13b are unnecessary.

Further, the inside wall surface at the top side of this sealing member 13 is provided with first positioning pins 13c sticking out downward. When connecting a compatible design HIFIX to the handler 10, the first positioning pins 13c are inserted into the first positioning holes 503a provided at the HIFIX whereby the HIFIX is positioned with respect to the handler 10.

As explained above, in the present embodiment, the size of the HIFIX 6 inserted into the opening 11a is smaller than the opening 11a of the handler 10, so an adapter 7 is interposed between the opening 11a and the HIFIX 5.

Below, this adapter 7 will be explained with reference to FIG. 5 to FIG. 8.

The adapter 7 according to the present embodiment adapts the shape of the HIFIX 5 to the opening 11a of the handler 10 to substantially fill in the space between the HIFIX 5 and the opening 11a. This adapter 7, as shown in FIG. 5 and FIG. 6, is comprised of a frame member 701 which covers the outer circumference of the spacing frame 503 of the HIFIX 5 in a rectangular frame shape and adapts the shape of the HIFIX 5 to the shape of the opening 11a.

Note that in the present embodiment, the frame member 701 covers the entire circumference of the spacing frame 503, but the present invention is not particularly limited to this. For example, the frame member may also cover only two facing sides at the outer circumference of the spacing frame. Further, for example, when the inside wall surface of the opening 11a is formed into a step shape, the frame member may cover the outer circumference of the HIFIX in a step shape so as to match with that stepped shape.

This frame member 701 comprises an upper layer part 702 with a cross-section of a substantial L-shape and a lower layer part 703 having a cross-section of a substantial L-shape and joined to the bottom of the upper layer part 702. The upper layer part 702 and lower layer part 703 are fastened by for example bolting or another technique so that the frame member 701 becomes recessed in cross-sectional shape. Further, the frame member 701 grips the outer circumference of the spacing frame 503 between the upper layer part 702 and the lower layer part 703.

The upper layer part 702, for example, is made of a glass epoxy resin or another material having a lower heat conductivity than the lower layer part 703. Due to this, the heat insulating property of the adapter 7 is secured, so the temperature environment in the test chamber 102 of the handler 10 can be maintained.

As opposed to this, the lower layer part 703, for example, is comprised of iron, stainless steel, or another material having a strength higher than the material forming the upper layer part 702. Due to this, it is possible to give the adapter 7 a strength able to withstand the strong pressing force applied from above at the time of a test.

The upper layer part 702 is formed at its upper surface with second positioning holes 706 having substantially the same shape as the first positioning holes 503a formed at the spacing frame 503 of the HIFIX 5.

Further, in the upper layer part 702, the inside wall surface facing the top surface of the spacing frame 503 is provided with second positioning pins 707 of substantially the same shape as the first positioning pins 13c provided at the sealing member 13 and projecting out downward. Due to this, it is possible to position an incompatible design HIFIX with respect to the handler in the same way as a compatible design HIFIX.

The lower layer part 703 is formed with a notch 704 at its outer circumference. This notch 704 is provided inside it with a second clamp piece 705 of substantially the same shape as the first clamp piece 515 provided at the HIFIX 5. Due to this, the rod 12a of the existing cylinder 12 can press against the first clamp piece 515 to fix an incompatible design HIFIX.

The thus configured adapter 7 is used as follows.

First, before connecting the HIFIX 5 to the handler 10, the upper layer part 702 and lower layer part 703 of the frame member 701 grip and fasten the outer circumference of the spacing frame 503 and attach the adapter 7 to the HIFIX 5. Due to this, an incompatible design HIFIX becomes a connecting structure the same as a compatible design HIFIX. Note that by attaching the adapter 7 to the HIFIX 5 in advance, the attachment work of the adapter 7 becomes work from above, so the work efficiency is superior.

When attaching the adapter 7 to the HIFIX 5, the second positioning pins 707 provided at the adapter 7 are inserted into the first positioning holes 503a provided in the HIFIX 5. Due to this, the HIFIX 5 is positioned with respect to the adapter 7.

Next, the HIFIX 5 to which the adapter 7 is attached is inserted into the opening 11a formed in the base 11 of the handler 10. At this time, the first positioning pins 13c provided at the sealing member 13 of the handler 10 are inserted into the second positioning holes 706 provided at the adapter 7. Due to this, the adapter 7 is positioned with respect to the handler 10. As a result, the HIFIX 5 is positioned through the adapter 7 with respect to the handler 10.

Next, the cylinder 12 makes the rod 12a extend whereby the front end of the rod 12a contacts and presses upward the second clamp piece 705 provided at the adapter 7. Due to this, the cylinder 12 holds the adapter 7, so as a result the HIFIX 5 is held through the adapter 7 by the cylinder 12.

Further, when contacting the rod 12a and second clamp piece 705, the wedge action of the taper surface causes the HIFIX 5 to be pressed upward and the adapter 7 to be pressed against the sealing member 13. Since the adapter 7 and the sealing member 13 have the packings 13a, 13b interposed between them, this pressing action secures the air-tightness of the test chamber 102.

In this way, in the present embodiment, the adapter 7 is used to adapt the shape of an existing HIFIX 5 to the opening of the handler 10, so even if the handler 10 has an enlarged opening 11a, the existing HIFIX 5 can be used as it is. For this reason, it is not necessary to fabricate new HIFIX's, so the cost of electronic device test apparatus 1 can be reduced.

Note that the above-mentioned embodiment was described to facilitate understanding of the present invention and was not described to limit the present invention. Therefore, the elements disclosed in the above embodiment include all design changes and equivalents falling under the technical scope of the present invention.

For example, in the above-mentioned embodiment, the adapter 7 was explained as being fixed to the DSA 501 side of the HIFIX 5, but the present invention is not particularly limited to this. The adapter may also be fixed to the handler side. As an example of the structure in this case, a structure where the lower layer part 703 in FIG. 8 can move horizontally due to the pressing action of the rod 12a and the taper of the lower layer part 703 contacts the taper of the first clamp piece 515 of the DSA 501 and presses the DSA 501 upward may be mentioned.

Further, in the above-mentioned embodiment, as a specific example of the mechanism for holding and fixing the HIFIX, the cylinder 12 and rod 12a shown in FIG. 8 maybe mentioned, but the present invention is not particularly limited. For example, a holding mechanism such as for example a rotary clamp mechanism may be used.

Further, in the above-mentioned embodiment, the first positioning pins 13c were explained as being provided at the sealing member 13, but the present invention is not particularly limited to this. The first positioning pins 13c may also be provided at positions other than the sealing member 13. Further, instead of the first positioning pins 13c, it is also possible to employ a positioning structure other than pins.

Further, the second positioning pins 707 may be attached to the upper layer part 702 by bolts etc. In this case, the DSA 501 can be easily attached to the adapter 7.

Further, in the above-mentioned embodiment, as shown in FIG. 8, the case where the first clamp piece 515 and the second clamp piece 705 are the same in height was explained, but when a compatible design HIFIX and incompatible design HIFIX differ in height of the DSA 501, this difference may be absorbed by designing the position of the height direction of the second clamp piece 705. Due to this, the advantage that the existing expensive HIFIXes 5 can be used as they are.

1. An adapter interposed between an opening formed in a handler and an interface attached to a test head and inserted into said opening and adapting a shape of said interface to the shape of said opening.

2. An adapter as set forth in claim 1, having a frame member adapting a shape of an insertion part of said interface to be inserted into said opening to a shape of said opening.

3. An adapter as set forth in claim 1, having a frame member adapting a shape of said opening to a shape of an insertion part of said interface to be inserted into said opening.

4. An adapter as set forth in claim 2, wherein said frame member has a recessed cross-sectional shape surrounding the outer circumference of said insertion part.

5. An adapter as set forth in claim 2, wherein said insertion part in said interface is a spacing frame of said interface.

6. An adapter as set forth in claim 2, wherein
said frame member has an upper layer part and a lower layer part joined below said upper layer part,
said upper layer part is comprised of a material having a lower heat conductivity than the material forming said lower layer part, and
said lower layer part is comprised of a material having a higher strength than the material forming said upper layer part.

7. An interface attached to a test head for testing an electronic device under test and interconnecting an electrical connection between said electronic device under test and said test head,
the interface provided with an adapter as set forth in claim 1.

8. An electronic device test apparatus comprising:
a test head to which an electronic device under test is electrically connected,
a tester for testing said electronic device under test through said test head, and
a handler for feeding a pretest electronic device to said test head and discharging a tested electronic device from said test head, wherein
said electronic device test apparatus comprises an adapter as set forth in claim 1.

9. An electronic device test apparatus as set forth in claim 8, wherein
said handler comprises a holding device means for holding an interface,
said adapter is interposed between said holding device and said interface, and
said holding device holds said adapter so that said interface is held.

10. An electronic device test apparatus as set forth in claim 8, wherein
said handler comprises positioning device for positioning said interface with respect to said handler,
said adapter is interposed between said positioning device and said interface, and
said positioning device positions said adapter so that said interface is positioned with respect to said handler.

11. An electronic device test apparatus as set forth in claim 10, wherein:
said positioning device includes first positioning pins,
second positioning holes of substantially the same shape as first positioning holes provided at the interface for insertion of said first positioning pins are provided at said adapter and
second positioning pins of substantially the same shape as said first positioning pins are provided at said adapter, and
said first positioning pins are inserted into said second positioning holes and said second positioning pins are inserted into said first positioning holes, whereby said interface is positioned with respect to said handler.

12. An electronic device test apparatus as set forth in claim 8, wherein:
said handler comprises a sealing device for sealing the space between said opening and interface,
said adapter is interposed between said sealing device and said interface, and
said sealing device seals the space between said opening and said adapter.

13. An adapter interposed between an opening formed in a handler and an interface attached to a test head, and connecting said handler and said interface,
said adapter engaging with said interface to connect said handler and said interface.

14. An adapter interposed between an opening formed in a handler and an interface attached to a test head and connecting said handler and said interface,
said adapter interposed between an incompatible design interface not designed so as to match with the shape of said opening and said opening, and connecting said handler and said incompatible design interface.

15. An adapter as set forth in claim 13, attached by being fixed to said opening formed in said handler or attached by being fixed to said interface.

16. An adapter as set forth in claim 14, attached by being fixed to said opening formed in said handler or attached by being fixed to said interface.

17. An adapter as set forth in claim 3, wherein said frame member has a recessed cross-sectional shape surrounding the outer circumference of said insertion part.

18. An adapter as set forth in claim 3, wherein said insertion part in said interface is a spacing frame of said interface.

19. An adapter as set forth in claim 3, wherein
said frame member has an upper layer part and a lower layer part joined below said upper layer part,
said upper layer part is comprised of a material having a lower heat conductivity than the material forming said lower layer part, and
said lower layer part is comprised of a material having a higher strength than the material forming said upper layer part.
